(19) United States
(12) Patent Application Publication
(10) Pub. No.: US 2026/0245827 A1
(43) Pub. Date: Aug. 20, 2026

(54) SYSTEM FOR THE CONTINUOUS-WAVE LASER PROCESSING AND SEM CHARACTERISATION OF A SAMPLE

(71) Applicants: ECOLE POLYTECHNIQUE, PALAISEAU (FR); CENTRE NATIONAL DE LA RECHERCHE SCIENTIFIQUE, PARIS (FR)

(72) Inventors: Alexandre TANGUY, DOURDAN (FR); Manas UPADHYAY, MASSY (FR); Juan Guillermo SANTOS MACIAS, Madrid (ES)

(21) Appl. No.: 19/135,355

(22) PCT Filed: Oct. 12, 2023
(86) PCT No.: PCT/EP2023/078426

§ 371 Date: Jun. 3, 2025

(30) Foreign Application Priority Data
Dec. 16, 2022 (FR) 2213567

(51) Int. Cl. H01J 37/22; H01J 37/244; H01J 37/28

(52) U.S. Cl. CPC H01J 37/22; H01J 37/244; H01J 37/28; H01J 2237/24475; H01J 2237/2448

(57) ABSTRACT

A system for processing and characterizing a sample includes: a scanning electron microscope including a chamber, a device configured to generate an electron beam and to focus the electron beam onto the sample, at least one first detector, a laser source configured to generate a continuous-wave laser beam, a two-dimensional scanning device configured to move the laser beam over the sample at a defined speed, a focusing device configured to focus the laser beam onto the sample through the window and to modify a value of the focal length in a controlled manner, the laser source and the focusing device being configured so that the focusing spot on the sample has a defined power and a defined diameter.

### CROSS-REFERENCE TO RELATED APPLICATIONS

This application is a National Stage of International patent application PCT/EP2023/078426, filed on Oct. 12, 2023, which claims priority to foreign French patent application No. FR 2213567, filed on Dec. 16, 2022, the disclosures of which are incorporated by reference in their entireties.

### FIELD OF THE INVENTION

The present invention relates to the field of sample processing and characterization, applied to materials research and engineering, and more particularly using a continuous-wave laser for the processing and a scanning electron microscope for the characterization.

### BACKGROUND

Recent large-scale developments in industrial processes involve the development of materials by additive manufacturing using light/matter interaction. These processes lead to the formation of microstructures resulting from the strong thermal gradient to which these materials are subjected, which is also found in welding. Understanding the result of this out-of-equilibrium metallurgy requires ever more detailed knowledge of what happens during these processes, both for the purposes of study and for optimal practical implementation of these processes.

Today, this need for knowledge is only partially satisfied because of the complexity of the microstructures obtained and the capabilities of light interaction with matter. For example, the very high-precision characterization of the microstructures obtained from additive manufacturing requires the part to be withdrawn from the manufacturing line and inserted into a scanning electron microscope (SEM). The atmosphere in the additive machine is not controlled, and the sample may oxidize during processing, making characterization by SEM very difficult, if not impossible.

The publication “A novel combined device for laser modification in SEM” by K. Wetzig et al (SCANNING Vol 9, pages 99-107 (1987)) describes the association of a pulsed laser with an SEM, a sample arranged in the chamber of the SEM being illuminated by the very high-energy pulsed laser. The objective of this study is to carry out an in situ study of the physical processes implemented at a submicron scale during the irradiation of a surface by a pulsed laser at very high energy (3J per pulse with a duration of 10⁻³ or 10⁻⁸ s). An SEM image is taken before and after irradiation. The laser beam is focused with a biconvex lens that reduces the size of the laser spot by a factor of 10, and the focusing spot is fixed. The targeted applications are the laser ablation or evaporation of matter. This system is limited to a study/characterization of the effects induced on a metal sample by a very high-energy pulsed laser on a punctiform processing zone for destructive purposes.

An object of the present invention is to remedy the aforementioned drawbacks by proposing a versatile system, capable of processing a sample of material typically over a millimetric zone by a beam of energetic light, and of characterizing a large number of materials by an electron beam, and suitable for a wide variety of processes, some of which have been developed in recent years.

### SUMMARY OF THE INVENTION

The present invention relates to a system for processing and characterizing a sample, the system comprising:
a scanning electron microscope comprising:
a chamber containing a gas or under vacuum, in which said sample is arranged, and one wall of which comprises a window,
a device configured to generate an electron beam and to focus the electron beam onto the sample,
at least one first detector configured to detect electrons issuing from the sample,
a laser source configured to generate a continuous-wave laser beam,
a two-dimensional scanning device configured to move the laser beam over said sample at a defined speed,
a focusing device configured to focus the laser beam onto the sample through the window and to modify a value of the focal length in a controlled manner,
the laser source and the focusing device being configured so that the focusing spot on the sample has a defined power and a defined diameter.

According to one embodiment, the focusing device comprises an optical system of fixed focal length, and a device configured to modify said focal length and arranged upstream of the scanning device.

According to one embodiment, the system according to the invention comprises a beam splitter arranged upstream of the scanning device, and a display camera arranged on the path of an optical beam reflected by the sample, and reflected by the beam splitter, and configured for displaying the sample.

According to one embodiment, the system according to the invention comprises a thermal sensor configured to measure the temperature of a zone comprising the laser-focusing spot on the sample.

According to one embodiment, the system according to the invention further comprises a device (DIG) for injecting a defined gas into the chamber.

According to one embodiment, the first detector is a secondary electron detector.

According to one embodiment, the system according to the invention further comprises a second, removable detector configured to detect electrons backscattered by the sample.

According to one embodiment, the system according to the invention further comprises a removable crystallography camera (CC) configured to detect electrons backscattered by the sample.

According to one embodiment, the system according to the invention comprises a removable calorimeter for calibrating the laser output power.

According to one embodiment, the scanning electron microscope is of the environmental type.

According to one embodiment, the laser source is coupled to an optical fiber, and furthermore the laser source, the two-dimensional scanning device and the focusing device are arranged in a single housing, the system further comprising a coupling part configured to interface the housing and the scanning electron microscope.

According to another aspect, the invention relates to a method for processing and characterizing a sample, the sample being arranged in a chamber of a scanning electron microscope, the chamber comprising a gas or being under vacuum, a wall of the chamber comprising a window, the method comprising:
a step 100 of generating a continuous-wave laser beam having a modifiable power,
a processing step 200 comprising focusing the laser beam onto the sample by passing it through the window, the value of the focal length being modifiable in a controlled manner, and the two-dimensional scanning of the laser beam so as to move it over said sample at a defined speed, the focusing spot on the sample having a defined power and a defined diameter,
a characterization step 300 consisting in producing a first image, called a post-processing image, with the scanning electron microscope, by illuminating the sample with a focused electron beam and detecting electrons issuing from the sample.

According to one embodiment, the method according to the invention further comprises a step 50 consisting in producing a second image, called a pre-processing image, with the scanning electron microscope before the processing step 200.

The following description presents several exemplary embodiments of the device of the invention: these examples do not limit the scope of the invention. These exemplary embodiments not only contain the features essential to the invention but also additional features associated with the embodiments in question.

### BRIEF DESCRIPTION OF THE DRAWINGS

The invention will be better understood and other features, aims and advantages thereof will become apparent from the following detailed description, which is provided with reference to the appended drawings, which are defined by way of non-limiting examples and in which:

FIG. 1 illustrates a system according to the invention for processing and characterizing a sample.

FIG. 2 illustrates an example of implementation of the system according to the invention in which the SEM operates in “SE” mode, and comprising a display camera and a thermal camera.

FIG. 3 illustrates an example of implementation of the system according to the invention in which the SEM operates in “BSE” mode, and comprising a device for injecting a defined gas.

FIG. 4 illustrates an example of implementation of the system according to the invention in which the SEM operates in “EBSD” mode, and comprising a crystallography camera.

FIG. 4a illustrates an example of implementation of the system according to the invention in which the laser source, the output optical fiber, the two-dimensional scanning device and the focusing device are arranged in a single housing, and in which the system comprises a coupling part configured to interface the housing and the SEM.

FIG. 5 illustrates a first example of use of the system according to the invention with characterization in SEM mode.

FIG. 6 illustrates a second example of use of the system according to the invention with characterization in EBSD mode, the SEM image A being taken before processing, and the SEM image B being taken after processing.

FIG. 7 illustrates a third example of use of the system according to the invention with characterization in BSE mode.

### DETAILED DESCRIPTION

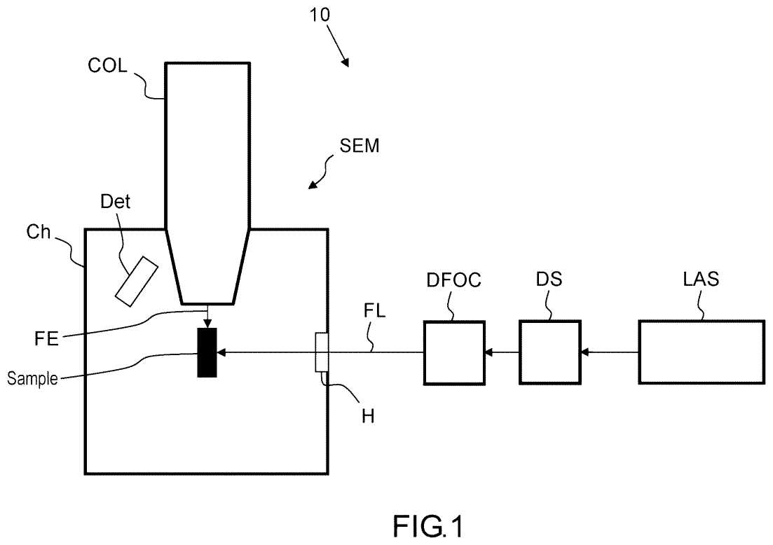

The system 10 according to the invention for processing and characterizing a sample is illustrated in FIG. 1. It comprises a scanning electron microscope SEM comprising a chamber Ch under vacuum or partial gas pressure, in which the sample to be processed/characterized is arranged. One of the walls of the SEM contains a window H. In a known manner, the SEM comprises a device COL (commonly referred to as a column) configured to generate an electron beam FE and to focus this electron beam onto the sample, and at least one detector Det configured to detect electrons issuing from the sample.

The system 10 according to the invention also comprises a laser source LAS configured to generate a continuous-wave laser beam FL, a focusing device DFOC configured to focus the laser beam onto the sample through the window H and to modify the value of the focal length in a controlled manner, and a two-dimensional scanning device DS configured to move the laser beam over said sample at a defined speed v.

The laser source LAS and the focusing device DFOC are configured so that the focusing spot on the sample has a defined power P and a defined diameter D. In order to vary P, the power of the laser, which is adjustable, is varied, and in order to vary D, the value of the focal length is varied. The beam FL enters the chamber Ch via an interface window H, which is preferably laser-quality treated (specific surface treatment). The window is transparent to the wavelength of the laser and also ensures the sealing of the chamber. The window seals the chamber and allows the laser beam FL to enter the chamber Ch and access the sample.

Typically, an SEM image of the sample is taken after laser processing, and optionally also before processing for comparison.

The invention thus makes it possible to process and characterize a sample of material in the same instrument, with a continuous-wave laser beam whose parameters (P, D, v) can be modified.

With the use of a continuous-wave laser, the energy input is constant over time and according to a fully controlled thermal gradient. This permits the study and implementation of physical and chemical processes:
modification of the material, such as change of state or of phase, change of microstructure or of surface state, evolution of roughness, assembly, etc.,
restoration or repair (solidification or resolidification).

With the system according to the invention, the spot parameters P (power) and D (size) are adjustable, which makes it possible to adapt the surface energy density incident on the sample, and the temperature gradient to which it is subjected, which can reach one million degrees/cm. Typically, the diameter of the beam varies, depending on the application, over a range within the interval [45-500 μm].

In addition, the sample is processed in the controlled atmosphere (vacuum, humidity, neutral gas or reducing gas, etc.) of the chamber Ch of the SEM. For example, laser processing under vacuum preserves the sample from damage by moisture and oxidation.

The adjustment of the scanning speed v of the device DS provides a multi-scale character, with an accessible scanning amplitude typically ranging from the micron to the millimeter, and it is also possible to complicate the shape of the scanning (scanning strategy).

The factors of time, temperature and atmosphere are thus controlled.

By virtue of the system according to the invention integrating the control of the aforementioned parameters, it is possible to increase the surface quality and the mechanical properties of the material of the sample. It is also possible to obtain new properties of the laser-processed material, by changing its local microstructure, and to characterize the changes produced by the laser processing.

The system according to the invention can be implemented with various materials such as ceramics, minerals, metals, polymers, etc.

The scientific study of the results obtained with the system according to the invention opens up a field of experimental and numerical knowledge.

With the system according to the invention, it is possible to reproduce heat treatment similar to that which takes place in various industrial processes (additive manufacturing, heat treatment, annealing, tempering, welding, etc.), making it possible to understand the nature of the interactions between industrial lasers and materials during these processes, and to propose optimized heat treatments during and/or after the implementation of these processes.

The system according to the invention also finds a place in industrial centers, for example of additive manufacturing or surface structuring. It makes it possible to control the in situ evolution of the material processed by the laser. The system according to the invention is integrated upstream or downstream of a process for verifying the consequence or consequences of modification of a manufacturing parameter on the evolution of the microstructure of the material.

The system according to the invention for processing and characterizing a sample is thus extremely versatile and meets a need for equipment that has not been met to date, as explained above.

The system according to the invention has various embodiments that can be combined with one another.

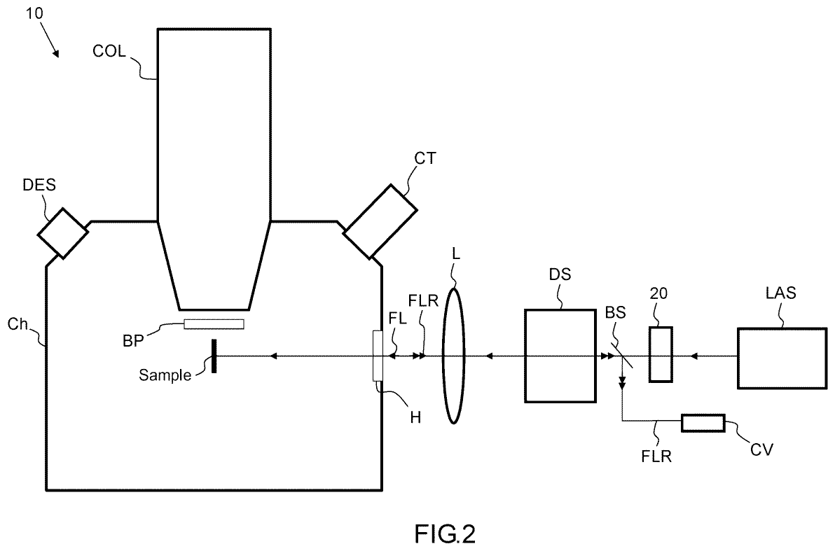

According to an embodiment illustrated in FIG. 2, the focusing device comprises an optical system L of fixed focal length, and a device 20 configured to modify the value of the focal length and arranged upstream of the scanning device, the latter itself arranged upstream of the optical system L. The device 20 is, for example, a varioScanR which comprises a divergent lens that causes the beam to diverge at the laser output, and which therefore makes it possible to modify the size of the laser spot impacting the sample.

The scanning device is, for example, a goniometric mirror.

Accessories, also illustrated in FIG. 2, permit visualization of the zone of impact of the beam on the sample.

According to one embodiment, the system also comprises a beam splitter BS arranged upstream of the scanning device, and a display camera CV arranged on the path of the optical beam FLR reflected by the sample and then by the beam splitter BS. The visible camera thus recovers the light reflected by the sample, which makes it possible to visualize the surface of the sample, the future path of the laser and also the location where the laser spot has passed.

According to another embodiment, the system 10 according to the invention comprises a thermal sensor CT for measuring the temperature of a zone comprising the laser-focusing spot on the sample. Preferably, a 2D thermal camera is used which makes it possible to carry out infrared thermography, for example to visualize the distribution of the temperature field induced by the laser treatment.

In FIG. 2, the electron detector shown is an electron detector commonly called a secondary electron detector DES, conventionally used in scanning electron microscopy operating in secondary electron mode. Conventionally, this mode is installed by default in commercial SEMs and makes it possible to obtain a topographical contrast image of the observed surface.

FIG. 2 also shows a removable protective shield BP, which protects the SEM column during laser firing.

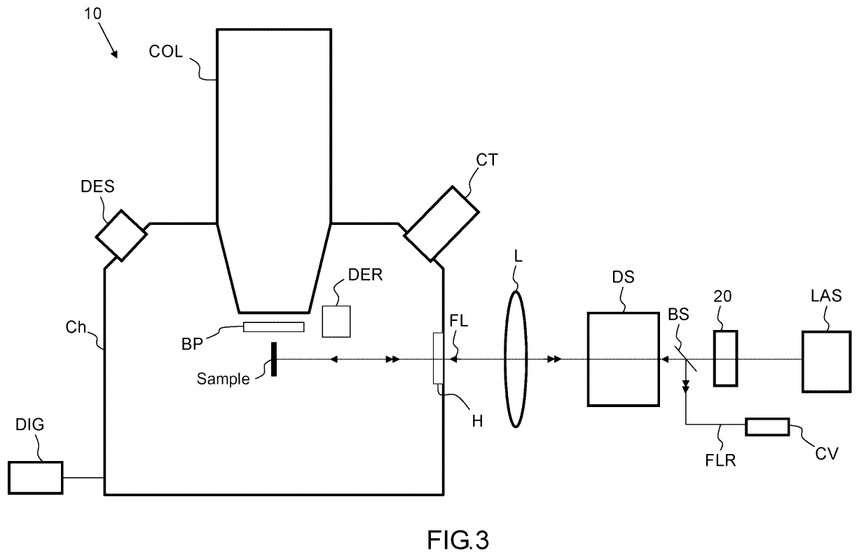

FIG. 3 illustrates an embodiment of the system according to the invention in which the SEM operates in backscattered electron (BSE) mode. This mode produces an atomic number contrast image allowing information to be obtained on the chemical nature of the observed elements. In this mode the system comprises a second electron detector which is a backscattered electron detector DER. This detector is preferably removable and is only positioned in the chamber when the SEM has to operate in this mode.

According to an embodiment also illustrated in FIG. 3, the system 10 comprises a device DIG for injecting a defined gas into the chamber Ch, which allows control of the environment during the laser processing.

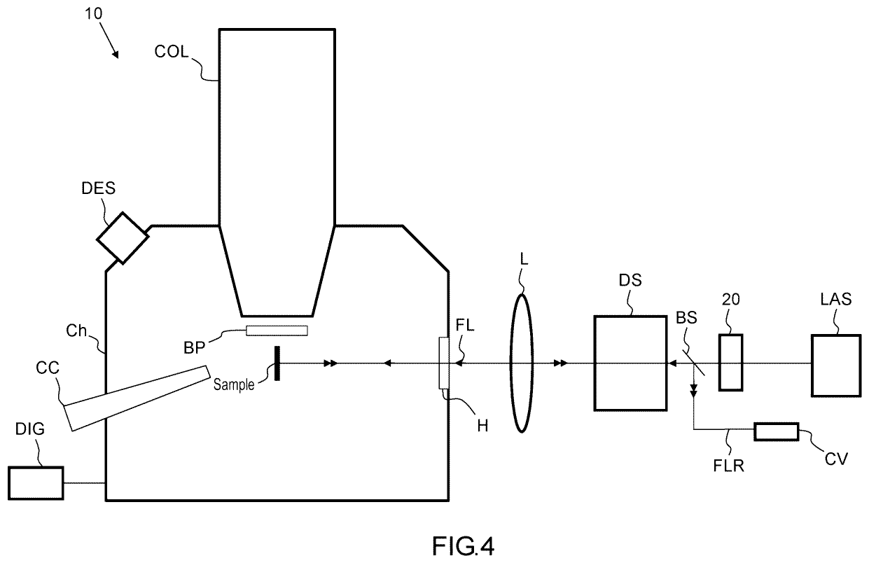

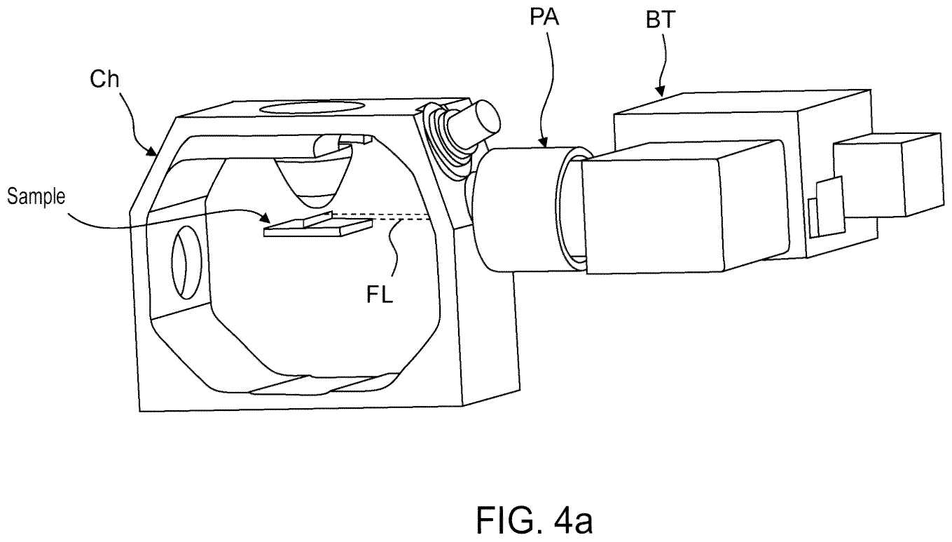

FIG. 4 illustrates an embodiment of the system according to the invention in which the SEM operates in electron backscattered diffraction (EBSD) mode. In this mode the system comprises a removable crystallography camera CC configured to detect electrons backscattered/diffracted by the sample. This mode makes it possible to look at the result of the laser processing in order to characterize the microstructure from a crystallography point of view (specific imaging).

According to one embodiment, the scanning microscope is of the environmental type, or ESEM, which allows monitoring of the gaseous environment of the part that is to be treated. In addition, the use of an ESEM in the system according to the invention allows implementation of all related physical and chemical techniques, using particle physics (X-ray spectrometry, electron diffraction, IR thermography).

According to one embodiment, the system comprises a removable calorimeter for calibrating the laser output power.

According to a non-limiting example, the laser LAS is a class 4 fiber laser with an adjustable fiber output power of 20 to 200 W (collimated beam) and emitting at a wavelength of 1070 +/−2 nm.

According to one embodiment, the laser is a laser coupled to an output optical fiber. The laser source, the output optical fiber, the two-dimensional scanning device and the focusing device are arranged in a single housing BT. According to one embodiment, the system also comprises a coupling part PA configured to interface the housing and the SEM, as is illustrated in FIG. 4a. This part makes it possible to confine the focusing lens of the housing.

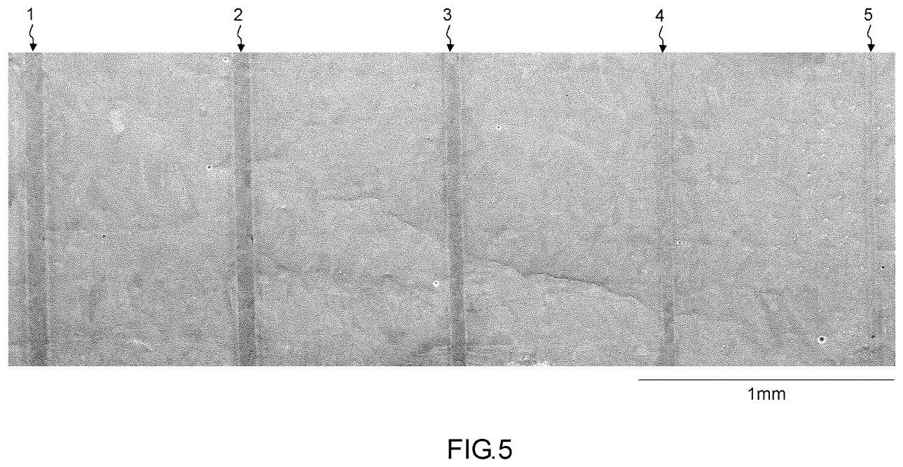

FIG. 5 illustrates a first example of use of the system according to the invention. This secondary electron image (SEM) makes it possible to identify the location and evaluate the width of the zone affected by the passage of the laser. In this experiment, five laser shots were made with a power of 24 W and with a spot size of 60 μm. Tracks 1 to 5 correspond to a laser advance speed of 50, 100, 250, 500 and 1000 mm/s, respectively.

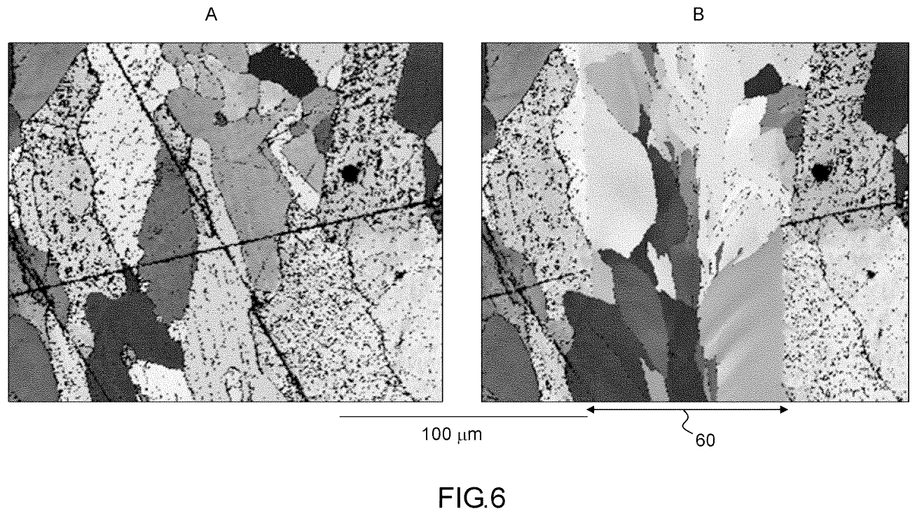

FIG. 6 illustrates a second example of use of the system according to the invention; image A is the image before the laser processing and image B is the image after the laser processing. The analysis of the backscattered electron diffraction type obtained with the EBSD camera reveals the crystallographic character of the microstructure of the material and the modification of the latter by the laser. The comparison of images A (before laser processing) and B (after laser processing) shows that the grains constituting the microstructure and the surface state are modified by the passage of the laser (zone 60).

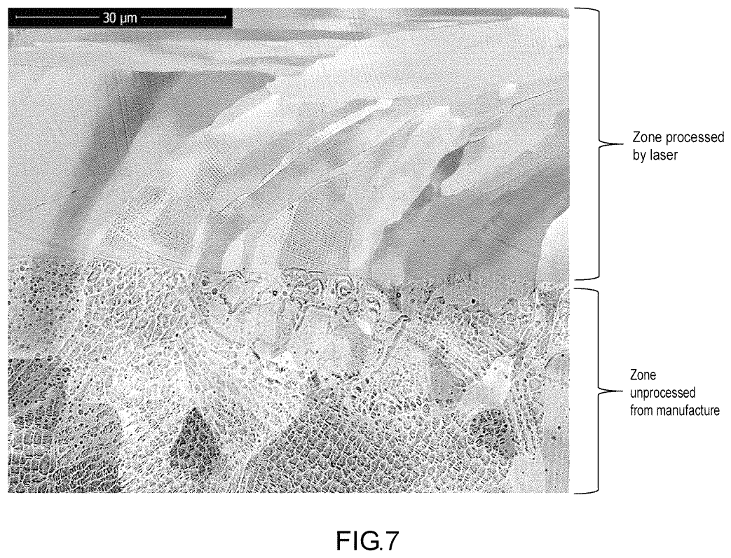

FIG. 7 illustrates a third example of use of the system according to the invention. The backscattered electron imaging (BSE mode) obtained with the electron microscope reveals the contrast of chemical composition constituting the microstructure of the observed material and the modification of the latter by the laser. The lower part (unprocessed zone) shows the network (lighter in the image due to chromium and molybdenum enrichment) and the cells (interconnected honeycomb network, darker in the image). The processed upper part shows that the network is modified; its topography is greatly diminished and the cells are smaller. This change in structure induces modifications in the mechanical properties of the material.

Thus, the system according to the invention permits in situ comparison before/after processing, without moving the sample between the laser processing and the characterization. This comparison of images taken in situ represents a significant saving of time, and the use of the system according to the invention leads to more reliable measurements, because they are carried out under a controlled atmosphere.

According to another aspect, the invention relates to a method for processing and characterizing a sample. The sample is arranged in the chamber Ch of an SEM, the chamber comprising a gas or being under vacuum. One wall of the chamber comprises a window H. The method comprises a step 100 of generating a continuous-wave laser beam FL having a modifiable power P. Then, in a processing step 200, the laser beam is focused onto the sample by passing through the window, and the laser beam is scanned in two dimensions so as to move it over the sample at a defined speed v. The value of the focal length can be modified in a controlled manner, the focusing spot on the sample having a defined power P and a defined diameter D. Finally, in a characterization step 300, a first image, called a post-processing image, is produced with the SEM, by illuminating the sample with a focused electron beam FE and detecting electrons issuing from the sample.

According to one embodiment, the method according to the invention further comprises a step 50 consisting in producing a second image, called a pre-processing image, with the SEM before the processing step 200.

1. A system for processing and characterizing a sample, the system comprising:
a scanning electron microscope (SEM) comprising:
a chamber (Ch) containing a gas or under vacuum, in which said sample is arranged, and one wall of which comprises a window (H),
a device (COL) configured to generate an electron beam (FE) and to focus the electron beam onto the sample,
at least one first detector (Det) configured to detect electrons issuing from the sample,
a laser source (LAS) configured to generate a continuous-wave laser beam (FL),
a two-dimensional scanning device (DS) configured to move the laser beam over said sample at a defined speed (v),
a focusing device (DFOC) configured to focus the laser beam onto the sample through the window and to modify a value of the focal length in a controlled manner,
the laser source and the focusing device being configured so that the focusing spot on the sample has a defined power (P) and a defined diameter (D).

2. The system as claimed in claim 1, wherein the focusing device comprises an optical system (L) of fixed focal length, and a device configured to modify said focal length and arranged upstream of the scanning device.

3. The system as claimed in claim 1, comprising a beam splitter (BS) arranged upstream of the scanning device, and a display camera (CV) arranged on the path of an optical beam (FLR) reflected by the sample, and reflected by the beam splitter, and configured for displaying the sample.

4. The system as claimed in claim 1, comprising a thermal sensor (CT) configured to measure the temperature of a zone comprising the laser-focusing spot on the sample.

5. The system as claimed in claim 1, claims, further comprising a device (DIG) for injecting a defined gas into the chamber.

6. The system as claimed in claim 1, claims, wherein the first detector is a secondary electron detector (DES).

7. The system as claimed in claim 1, claims, further comprising a second, removable detector (DER) configured to detect electrons backscattered by the sample.

8. The system as claimed in claim 1, further comprising a removable crystallography camera (CC) configured to detect electrons backscattered by the sample.

9. The system as claimed in claim 1, claims, comprising a removable calorimeter for calibrating the laser output power.

10. The system as claimed in claim 1, claims, wherein the scanning electron microscope is of the environmental type (ESEM).

11. The system as claimed in claim 1, wherein the laser source is coupled to an optical fiber, and wherein the laser source, the two-dimensional scanning device and the focusing device are arranged in a single housing, the system further comprising a coupling part configured to interface the housing and the scanning electron microscope.

12. A method for processing and characterizing a sample, the sample being arranged in a chamber (Ch) of a scanning electron microscope (SEM), the chamber comprising a gas or being under vacuum, a wall of said chamber comprising a window (H), the method comprising:
a step of generating a continuous-wave laser beam (FL) having a modifiable power (P),
a processing step comprising focusing the laser beam onto the sample by passing it through the window, the value of the focal length being modifiable in a controlled manner, and the two-dimensional scanning of the laser beam so as to move it over said sample at a defined speed (v), the focusing spot on the sample having a defined power (P) and a defined diameter (D),
a characterization step consisting in producing a first image, called a post-processing image, with the scanning electron microscope, by illuminating the sample with a focused electron beam (FE) and detecting electrons issuing from the sample.

13. The method as claimed in claim 12, further comprising a step of producing a second image, called a pre-processing image, with the scanning electron microscope before the processing step.
